(19) United States
(12) Patent Application Publication
(10) Pub. No.: US 2011/0147840 A1
(43) Pub. Date: Jun. 23, 2011

(54) WRAP-AROUND CONTACTS FOR FINFET AND TRI-GATE DEVICES

(76) Inventors: Stephen M. Cea, Hillsboro, OR (US); Rishabh Mehandru, Beaverton, OR (US); Lucian Shifren, Hillsboro, OR (US); Kelin Kuhn, Aloha, OR (US)

(21) Appl. No.: 12/646,651

(22) Filed: Dec. 23, 2009

(51) Int. Cl. H01L 27/12; H01L 21/86

(52) U.S. Cl. 257/347; 438/151; 257/350; 438/155; 257/E21.704; 257/E27.112

(57) ABSTRACT

A semiconductor device comprises a substrate and a semiconductor body formed on the substrate. The semiconductor body comprises a source region; and a drain region. The source region or the drain region, or combinations thereof, comprises a first side surface, a second side surface, and a top surface. The first side surface is opposite the second side surface, the top surface is opposite the bottom surface. The source region or the drain region, or combinations thereof, comprise a metal layer formed on the substantially all of the first side surface, substantially all of the second side surface, and the top surface.

### BACKGROUND

In conventional finFET and Tri-gate transistor devices, the contact area for source and drain regions, which is the top of the source and drain regions, is constant as the fin height increase, thereby causing non-optimal drive current scaling as the fin height increases due to a small contact interface area. Consequently, the areas on the top of source and drain regions of a conventional finFET and Tri-gate transistor devices remains substantially constant as the height of the fin increases.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts an exemplary finFET, or Tri-gate, transistor 100 according to the subject matter disclosed herein;

FIGS. 2A-2I depict a sequence of process steps for forming a contact structure according to the subject matter disclosed herein; and

FIG. 3 depicts a process flow corresponding to the sequence of process steps depicted in FIGS. 2A-2I.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of contact structures for finFETs and Tri-gate devices are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. The word “exemplary” is used herein to mean “serving as an example, instance, or illustration.” Any embodiment described herein as “exemplary” is not to be construed as necessarily preferred or advantageous over other embodiments.

The subject matter disclosed herein relates to contact structures for a finFET, or Tri-Gate, transistor device that utilizes a wrap-around structure so that contact area advantageously scales as the fin height increases. That is, the contact area proportionally increases areas as the height of the fin increases according to the subject matter disclosed herein.

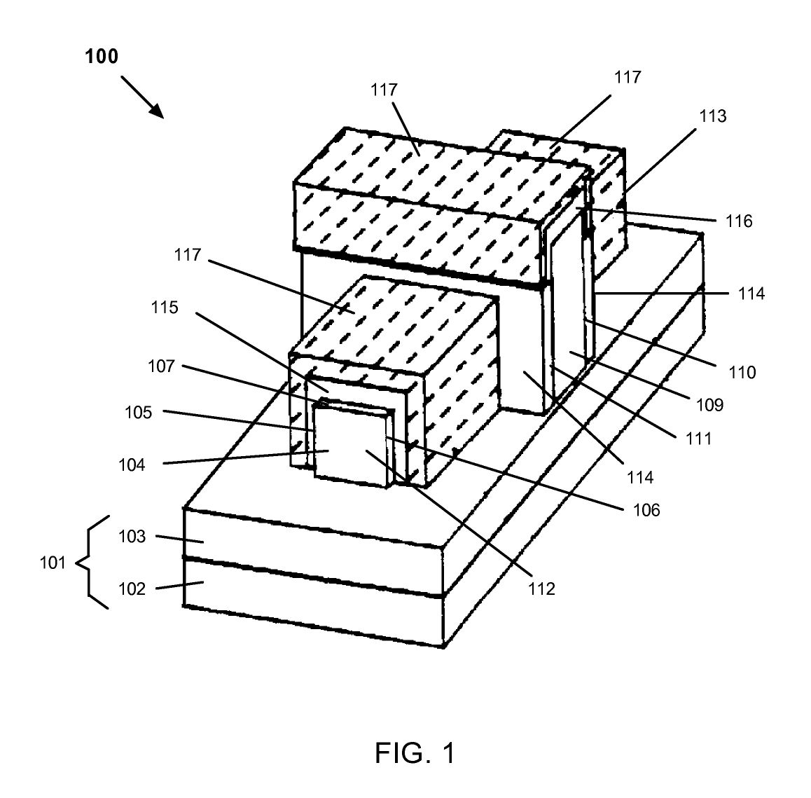

FIG. 1 depicts an exemplary finFET, or tri-gate, transistor 100 according to the subject matter disclosed herein. Tri-gate transistor 100 is formed on a substrate 101. In an exemplary embodiment, substrate 101 is an insulating substrate that comprises a lower monocrystalline silicon substrate 102 upon which is formed an insulating layer 103, such as a silicon-dioxide film. Tri-gate transistor 100 can, however, be formed on any insulating substrate, such as substrates formed from silicon dioxide, nitrides, oxides, or sapphires. In an exemplary embodiment, substrate 101 can be a semiconductor substrate, such as, but not limited to, a monocrystalline silicon substrate or a gallium-arsenide substrate. In yet another exemplary embodiment, substrate 101 could be a bulk structure form from, for example, all silicon.

Tri-gate transistor 100 comprises a semiconductor body 104 formed on insulator 103 of insulating substrate 101. Semiconductor body 104 can be formed of any semiconductor material, such as, but not limited to, silicon, germanium, a silicon-germanium alloy, gallium arsenide, indium antimonide, gallium phosphide, gallimum antimonide or carbon nanotubes. Semiconductor body 104 can be formed of any material that can be reversibly altered from an insulating state to a conductive state by application of external electrical controls. In one exemplary embodiment, semiconductor body 104 is ideally a single crystalline film when the best electrical performance of transistor 100, is desired. For example, semiconductor body 104 is a single crystalline film when transistor 100 is used in high-performance applications, such as in a high-density circuit, such as a microprocessor. Semiconductor body 104, however, can be a polycrystalline film when transistor 100 is used in applications requiring less stringent performance, such as in a liquid crystal display. Insulator 103 insulates semiconductor body 104 from monocrystalline silicon substrate 101. In an exemplary embodiment, semiconductor body 104 comprises a single crystalline silicon film. Semiconductor body 104 comprises a pair of laterally opposite sidewalls 105 and 106 separated by a distance which defines a width of semiconductor body 104. Additionally, semiconductor body 104 comprises a top surface 107 that is opposite a bottom surface (not shown) that is formed on substrate 101. The distance between top surface 107 and the bottom surface (not shown) defines a body height. In one exemplary embodiment, the body height is substantially equal to the body width. In another exemplary embodiment, semiconductor body 104 has a width and a height that are less than about 30 nanometers and ideally less than about 20 nanometers. In yet another exemplary embodiment, the body height is between about one-half of body width to about two times body width.

Tri-gate transistor 100 further comprises a gate dielectric layer (not shown) formed on and around three sides of semiconductor body 104. The gate dielectric layer is formed on or adjacent to sidewall 105, on top surface 107, and on or adjacent to sidewall 106 of body 104. The gate dielectric layer can be formed from any gate dielectric material. In one exemplary embodiment, the gate dielectric layer comprises a silicon dioxide, silicon oxynitride or a silicon nitride dielectric layer. In another exemplary embodiment, the gate dielectric layer comprises a silicon oxynitride film formed to a thickness of between about 5 Å and about 20 Å. In yet another exemplary embodiment, the gate dielectric layer is a Hi-K gate dielectric layer, such as a metal-oxide dielectric, such as, but not limited to, tantalum pentaoxide, titantium oxide, hafnium oxide, hafnium silicon oxide, lanthanum oxide, lanthanum aluminum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, lead zinc niobate, and lead zirconate titanate (PZT).

Tri-gate device 100 further comprises a gate electrode 109. Gate electrode 109 is formed on and around the gate dielectric layer. That is, gate electrode 109 is formed on or adjacent to the gate dielectric on the three sides of semiconductor body 104 on which the gate dielectric is formed. Gate electrode 109 has a pair of laterally opposite sidewalls 110 and 111 that are separated by a distance that defines a gate length Lg of transistor 100. In an exemplary embodiment, the laterally opposite sidewalls 110 and 111 of gate electrode 109 run in a direction that is substantially perpendicular to the laterally opposite sidewalls 105 and 106 of semiconductor body 104.

Gate electrode 109 can be formed of any suitable gate electrode material. In one exemplary embodiment, gate electrode 109 comprises of polycrystalline silicon doped to a concentration density between about 1×10¹⁹ atoms/cm³ and about 1×10²⁰ atoms/cm³. In another exemplary embodiment, gate electrode 109 could be a metal gate electrode, such as, but not limited to, tungsten, tantalum, titanium, hafnium, zirconium, aluminum, ruthenium, palladium, platinum, cobalt, nickel, and their carbides and nitrides. In an exemplary embodiment, gate electrode 109 is formed from a material having a mid-gap work function between about 4.6 eV and about 4.8 eV. It should also be appreciated that gate electrode 109 need not necessarily be a single material, but could comprise a composite stack of thin films, such as, but not limited to, a polycrystalline silicon/metal electrode or a metal/polycrystalline silicon electrode.

Tri-gate transistor 100 also comprises a source region 120 and a drain region 130. Source region 112 and drain region 113 are formed in semiconductor body 104 on opposite sides of gate electrode 109, as shown in FIG. 1. Source region 112 and drain region 113 are formed of the same conductivity type, such as N-type or P-type conductivity. In an exemplary embodiment, source region 112 and drain region 113 comprise a doping concentration of between about 1×10¹⁹ atoms/cm³ and about 1×10²¹ atoms/cm³. Source region 112 and drain region 113 could be formed of a uniform concentration or could comprise subregions of different concentrations or doping profiles, such as tip regions (e.g., source/drain extensions). In one exemplary embodiment, when transistor 100 is a symmetrical transistor, source region 112 and drain region 113 will comprise the same doping concentration and profile. In another exemplary embodiment, when tri-gate transistor 100 is formed as an asymmetric transistor, then the doping concentration and profile of source region 112 and drain region 113 may vary in order to obtain a particular electrical characteristic. In another exemplary embodiment, source and drain regions 112 and 113 include a semiconductor film 115 that is formed on the exposed surfaces of semiconductor body 104 to form source and drain contact regions. In another exemplary embodiment, film 115 would be grown after recess etching the fin in the source-drain areas and film 115 would be used to strain the channel. One example would be strained silicon germanium SiGe. Another example would be strained silicon carbide SiC.

The portion of semiconductor body 104 located between source region 112 and drain region 113 defines a channel region (not shown) of transistor 100. The channel region could also be defined as the area of semiconductor body 104 surrounded by gate electrode 109. At times, however, the source/drain region may extend slightly beneath the gate electrode through, for example, diffusion to define a channel region slightly smaller than the gate electrode length Lg. In an exemplary embodiment, the channel region comprises intrinsic or undoped monocrystalline silicon. In one exemplary embodiment, the channel region comprises doped monocrystalline silicon. When the channel region is doped, it is typically doped to a conductivity level of between about 1×10¹⁶ atoms/cm³ to about 1×10¹⁹ atoms/cm³. In an exemplary embodiment, when the channel region is doped, the channel region is typically doped to the opposite conductivity type of source region 112 and drain region 113. For example, when the source and drain regions are N-type conductivity, the channel region would be doped to be P-type conductivity. Similarly, when the source and drain regions are P-type conductivity, the channel region would be doped to be N-type conductivity. In this manner, a tri-gate transistor 100 can be respectively formed into either a NMOS transistor or a PMOS transistor. The channel region could be uniformly doped or could be doped non-uniformly or with differing concentrations to provide particular electrical and performance characteristics. For example, the channel region could comprise “halo” regions, if desired.

One exemplary embodiment of transistor 100 comprises sidewall spacers 114 formed on the sidewalls of gate electrode 109. In another exemplary embodiment, source and drain regions 112 and 113 include a semiconductor film 115 that is formed on the exposed surfaces of semiconductor body 104 to form source and drain contact regions. In another exemplary embodiment, film 115 would be grown after recess etching the fin in the source-drain areas and film 115 would be used to strain the channel. One example would be strained SiGe. Additionally, if desired, a semiconductor film 116 can be formed on the top of gate electrode 109. Semiconductor film 116 could be a single crystalline film or a polycrystalline film. In one exemplary embodiment, semiconductor film 116 is an epitaxial (single crystalline) silicon film. In another exemplary embodiment, silicon film 115 is formed by a selective deposition process in which silicon is formed only on exposed regions that contain silicon, such as the exposed top surface and sidewalls of semiconductor body 104. A metal 117 is formed on the source and drain regions, as well as on the top of gate electrode 109. Metal 117 can be formed and can be formed from, for example, titanium, tungsten, nickel, copper, or cobalt, or any other metal or silicide contact that has a contact resistance equal to or better than NiSi. Metal 117 is formed on the source and drain regions to form source and drain contact regions so that contact area advantageously scales as the fin height increases. In an exemplary alternative embodiment, a silicide could be formed by reacting metal 117 with silicon or silicon germanium.

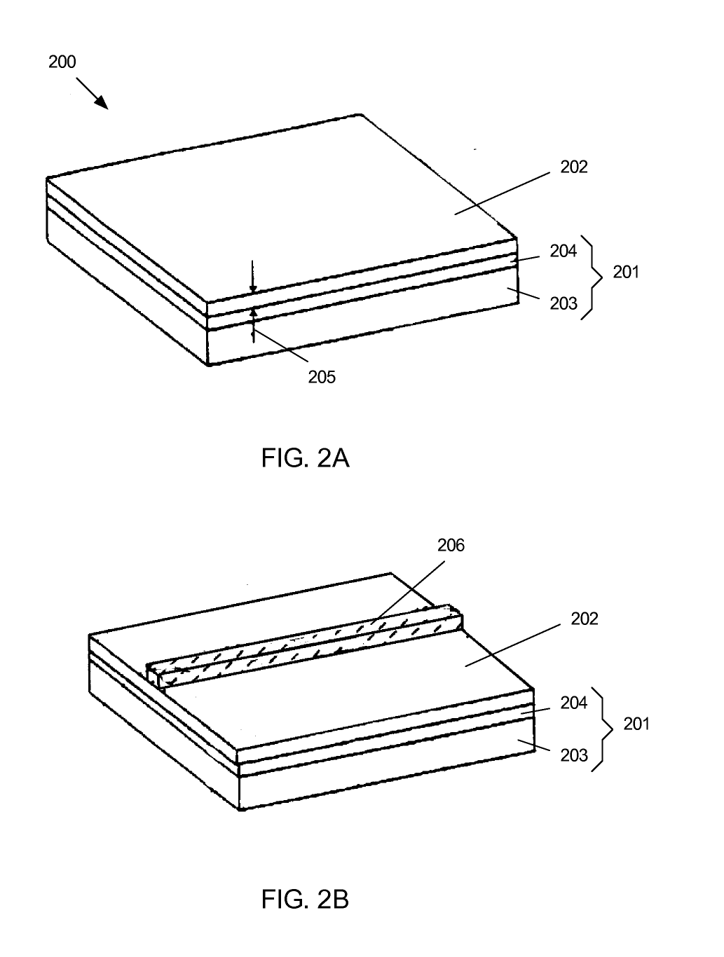

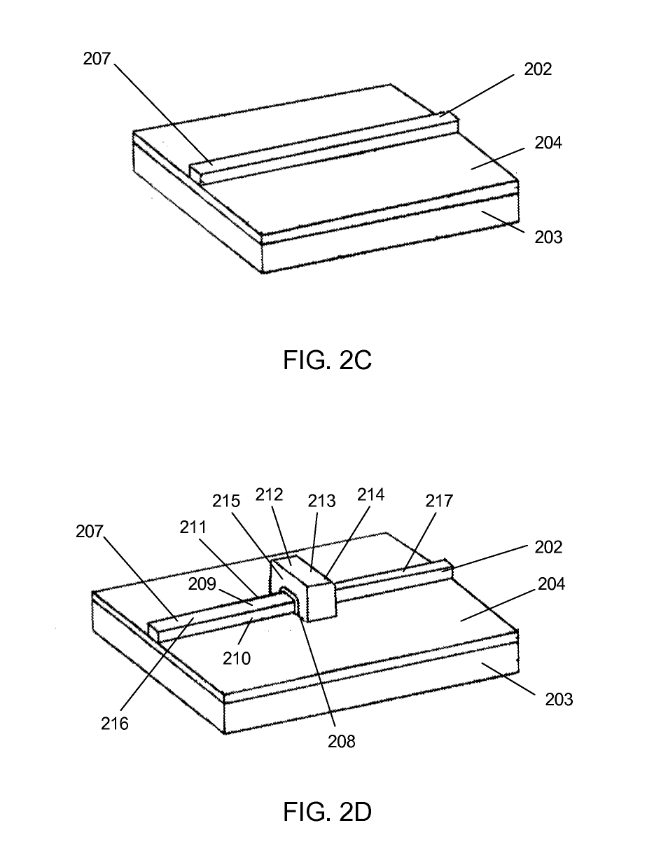

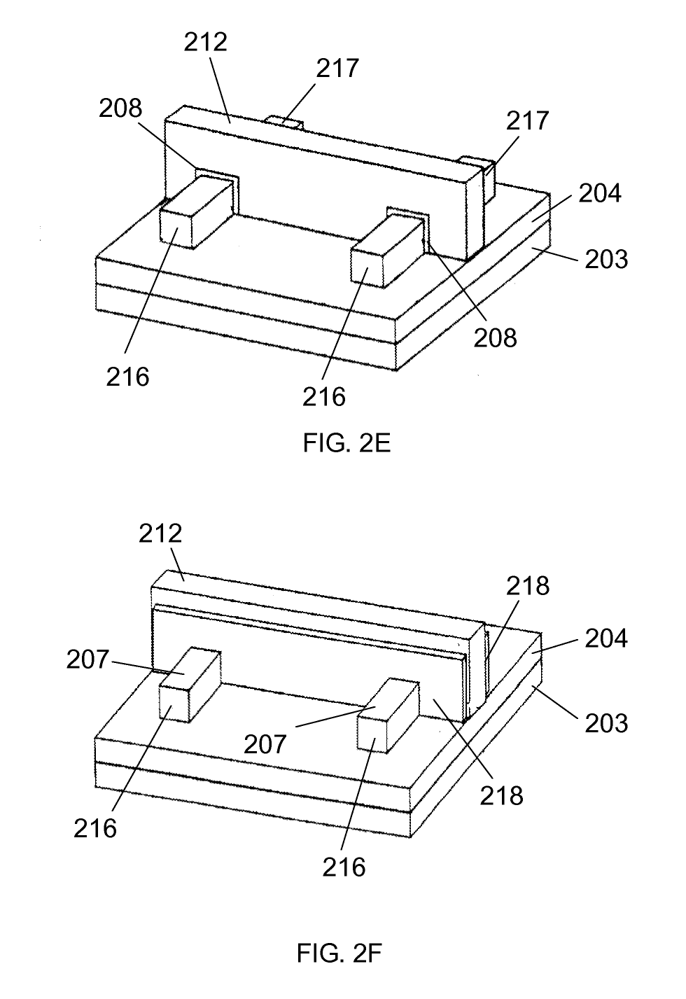

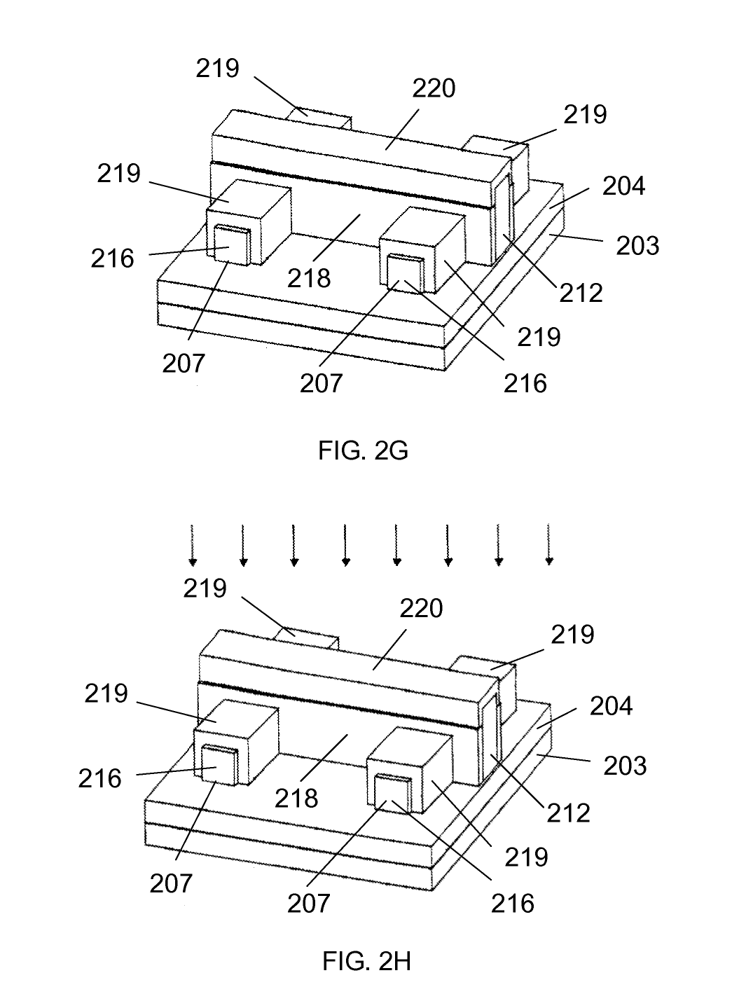

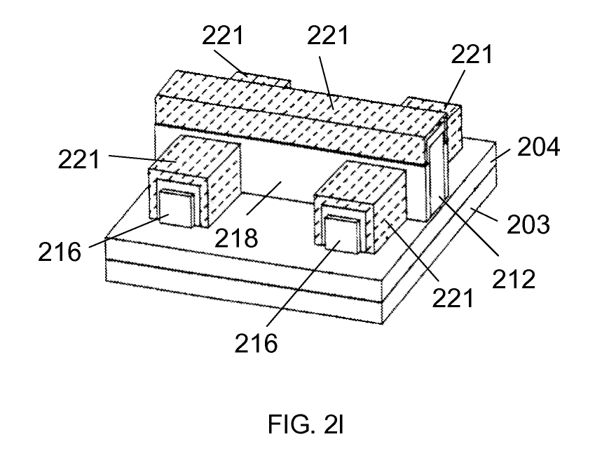

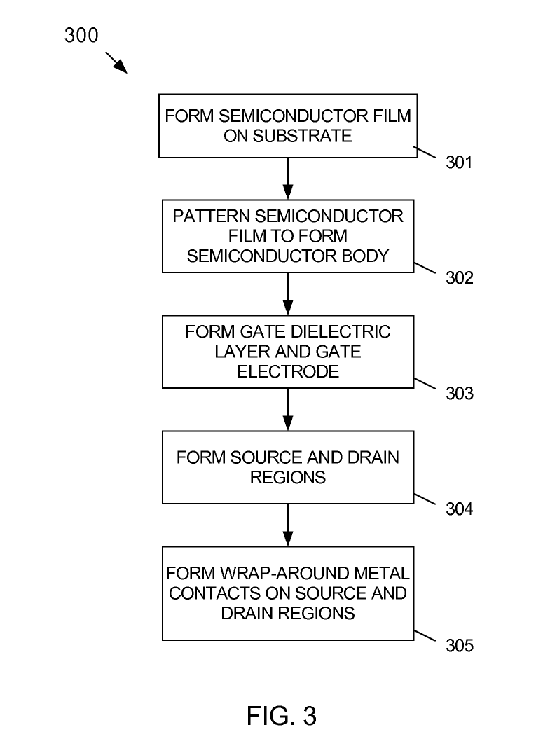

A method of fabricating a tri-gate transistor in accordance with embodiments of the subject matter disclosed herein is depicted in FIGS. 2A-2I. FIG. 3 is a flow diagram summarizing the process of fabricating a tri-gate transistor as depicted in FIGS. 2A-2I. Fabrication of a tri-gate transistor begins with a substrate 201. In one exemplary embodiment, a silicon or semiconductor film 202 is formed on substrate 201, as depicted in FIG. 2A. In another exemplary embodiment, substrate 201 comprises an insulating substrate, such as an oxide-based substrate. In still another exemplary embodiment, insulating substrate 201 comprises a bottom monocrystalline silicon substrate 203 and a top insulating layer 204, such as a silicon-dioxide film or silicon-nitride film. Insulating layer 204 isolates semiconductor film 202 from substrate 203. In one exemplary embodiment, insulating layer 204 is formed to have a thickness of between about 200 Å and about 2000 Å. Insulating layer 204 is sometimes referred to as a “buried oxide” layer. When a silicon or semiconductor film 202 is formed on an insulating substrate 201, a silicon or semiconductor-on-insulating (SOI) substrate 200 is created. In other exemplary embodiments, substrate 201 could be a semiconductor substrate, such as, but not limited to, a silicon monocrystalline substrate or a gallium-arsenide substrate.

Although semiconductor film 202 is a silicon film in one exemplary embodiment, in other exemplary embodiments semiconductor film 202 could be other types of semiconductor films, such as, but not limited to, germanium, a silicon germanium alloy, gallium arsenide, indium antimonide, gallium phosphide, gallimum antimonide, or carbon nanotubes. In one exemplary embodiment, semiconductor film 202 is an intrinsic (i.e., undoped) silicon film. In other exemplary embodiments, semiconductor film 202 is doped to a P-type or N-type conductivity having a concentration level between about 1×10¹⁶ atoms/cm³ and about 1×10¹⁹ atoms/cm³. Semiconductor film 202 could be doped (i.e., doped while semiconductor film 202 is deposited) or doped after semiconductor film 202 is formed on substrate 201 by, for example, ion-implantation. Doping after formation enables both PMOS and NMOS tri-gate devices to be fabricated easily on the same insulating substrate. The doping level of the semiconductor body at this point in the fabrication process determines the doping level of the channel region of the device.

Semiconductor film 202 is formed to a thickness that is approximately equal to the height desired for the subsequently formed semiconductor body or bodies of the fabricated tri-gate transistor. In one exemplary embodiment, semiconductor film 202 has a thickness, or height, 205 of less than about 30 nanometers and ideally less than about 20 nanometers. In another exemplary embodiment, semiconductor film 202 is formed to the thickness approximately equal to the gate “length” desired for the fabricated tri-gate transistor. In yet another exemplary embodiment, semiconductor film 202 is formed to be thicker than the desired gate length of the device. In still another exemplary embodiment, semiconductor film 202 is formed to a thickness that will enable the fabricated tri-gate transistor to be operated in a fully depleted manner for its designed gate length (Lg).

Semiconductor film 202 can be formed on substrate 201. Step 301 in FIG. 3 corresponds to this portion of fabricating a tri-gate transistor in accordance with embodiments of the subject matter disclosed herein. In one exemplary technique of forming a silicon-on-insulator (SOI) substrate, commonly known as the SIMOX technique, oxygen atoms are implanted at a high dose into a single crystalline silicon substrate and then annealed to form buried oxide 204 within the substrate. The portion of the single-crystalline silicon substrate above buried oxide 204 becomes silicon film 202. Another exemplary technique used to form SOI substrates is an epitaxial silicon-film transfer technique that is generally referred to as bonded SOI. In the bonded SOI technique, a first silicon wafer has a thin oxide grown on its surface that will later serve as the buried oxide 204 in the SOI structure. Next, a high-dose hydrogen implant is made into the first silicon wafer to form a high-stress region below the to silicon surface of the first wafer. The first wafer is then flipped over and bonded to the surface of a second silicon wafer. The first wafer is then cleaved along the high-stress plain created by the hydrogen implant resulting in an SOI structure comprising a thin silicon layer on top and the buried oxide underneath all on top of the single crystalline silicon substrate. Smoothing techniques, such as HC smoothing or chemical mechanical polishing (CMP), could be used to smooth the top surface of semiconductor film 202 to its desired thickness. In another exemplary alternative embodiment, substrate 201 could be formed from a bulk materials, such as silicon.

At this point in the fabrication process, isolation regions (not shown) could be formed in SOI substrate 200, if desired, in order to isolate the various transistors to be formed therein from one another. The isolation regions could be formed by etching away portions of the substrate film 202 surrounding a tri-gate transistor by, for example, photolithographic and etching techniques, and then backfilling the etched regions with an insulating film, such as SiO₂.

In order to form a tri-gate transistor on substrate 200, a photoresist mask 206 is formed on semiconductor film 202, as depicted in FIG. 2B. Photoresist mask 206 contains a pattern or plurality of patterns that define locations where one or more semiconductor bodies, or fins, will be subsequently formed in semiconductor film 202. Photoresist mask 206 could be formed by photolithographic techniques including masking, exposing, and developing a blanket-deposited photoresist film. The photoresist pattern defines the width desired of the subsequently formed semiconductor bodies, or fins, of a tri-gate transistor. In one exemplary embodiment, the pattern defines fins, or bodies, having a width that is equal to or greater than the width desired of the gate length Lg of the fabricated transistor. Accordingly, the most stringent photolithography constraints used to fabricate the transistor are associated with the gate electrode patterning and not the semiconductor body or fin definition. In one exemplary embodiment, the semiconductor to bodies, or fins, will have a width that is less than or equal to about 30 nanometers and ideally less than or equal to about 20 nanometers. In one exemplary embodiment, the patterns for the semiconductor bodies, or fins, have a width that is approximately equal to the silicon body height 205.

Additionally, photoresist mask 206 could also include patterns for defining locations where source landing pads (not shown) and drain landing pads (not shown) are to be formed. The landing pads (not shown) could be used to connect together the various source regions and to connect together the various drain regions of the fabricated transistor.

After forming photoresist mask 206, semiconductor film 202 is etched in alignment with photoresist mask 206 to form one or more silicon bodies 207, or fins 207 (FIG. 2C), and source and drain landing pads, if desired. Step 302 in FIG. 3 corresponds to this portion of fabricating a tri-gate transistor in accordance with embodiments of the subject matter disclosed herein. Semiconductor film 202 is etched until the underlying buried oxide layer 204 is exposed. Semiconductor etching techniques, such as anisotropic plasma etching or reactive ion etching, can be used to etch semiconductor film 202 in alignment with mask 206. After semiconductor film 202 has been etched to form one or more semiconductor bodies, or fins, 207 (and source/drain landing pads, if desired) the photoresist mask is removed using, for example, chemical stripping and O₂ ashing, to produce the substrate and semiconductor body, as depicted in FIG. 2C. In an exemplary alternative embodiment, wells and Vt implants could be formed.

Next, a gate dielectric layer 208 is formed on and around each semiconductor body 207, as depicted in FIG. 2D. That is, a gate dielectric layer 208 is formed on the top surface 209 of each semiconductor body 207 as well as on the laterally opposite sidewalls 210 and 211 of each semiconductor body 207. The gate dielectric can be a deposited dielectric or a grown dielectric. In one exemplary embodiment, the gate dielectric layer 208 is a silicon-dioxide dielectric film grown with a dry/wet oxidation process. In an exemplary embodiment, the silicon-dioxide film is grown to a thickness of between about 5 Å and about 15 Å. In another exemplary embodiment, gate dielectric film 207 is a deposited dielectric, such as, but not limited to, a high-dielectric-constant film, such as a metal oxide dielectric, such as tantalum pentaoxide and titanium oxide or other Hi-K dielectrics, such as zirconate titanate (PZT) or barium strontium (BST). A high-dielectric-constant film could be formed by, for example, chemical vapor deposition (CVD). In an exemplary alternative embodiment, dummy gates could be formed for a Hi-K/metal gate fabrication process.

After gate dielectric layer 208 is formed, a gate electrode 212 is formed. Step 303 in FIG. 3 corresponds to this portion of fabricating a tri-gate transistor in accordance with embodiments of the subject matter disclosed herein. Gate electrode 212 is formed on all sides of gate dielectric layer 208 as depicted in FIGS. 2D and 2E. FIG. 2E depicts two transistors that are coupled together through a single gate electrode 212, whereas FIG. 2D depicts only one transistor. Gate electrode 212 has a top surface 213 (FIG. 2D) that is opposite of a bottom surface (not shown, and which is formed on insulating layer 204) and has a pair of laterally opposite sidewalls 214 and 215. The distance between the laterally opposite sidewalls 214 and 215 defines the gate length Lg of the tri-gate transistor. In one exemplary embodiment, the gate length Lg is less than or equal to about 30 nanometers and ideally less than or equal to about 20 nanometers.

Gate electrode 212 can be formed by, for example, blanket depositing a suitable gate electrode material over the substrate as depicted in FIG. 2D. In one exemplary embodiment, gate electrode 212 is formed to a thickness of between about 200 Å and about 3000 Å. In another exemplary embodiment, gate electrode 212 has a thickness, or height, of at least three times the height of semiconductor body 208. The gate electrode material is then patterned using photolithography and etching techniques to form gate electrode 212 from the gate electrode material. In one exemplary embodiment, the gate electrode material comprises polycrystalline silicon. In another exemplary embodiment, the gate electrode material comprises a polycrystalline silicon-germanium alloy. In yet other exemplary embodiments, the gate electrode material could comprise a metal film, such as tungsten, tantalum, and their nitrides.

Next, a source 216 and a drain region 217 for the transistor are formed in semiconductor body 208 on opposite sides of gate electrode 212. In an exemplary alternative embodiment, tips and spacers could be formed. Step 304 in FIG. 3 corresponds to this portion of fabricating a tri-gate transistor in accordance with embodiments of the subject matter disclosed herein. In one exemplary embodiment, source region 216 and drain region 217 include tip or source/drain extension regions (not shown). Such source and drain extension regions can be formed by placing dopants into semiconductor body 207 on both sides of gate electrode 212 in order to form the tip regions. If source and drain landing pads (not shown) are utilized, the source and drain landing pads may be doped at this time also. For a PMOS tri-gate transistor, the semiconductor fin, or body 208, is doped to a P-type conductivity and to a concentration between about 1×10²⁰ atoms/cm³ and about 1×10²¹ atoms/cm³. For a NMOS tri-gate transistor, the semiconductor fin, or body 208, is doped with N-type conductivity ions to a concentration between about 1×10²⁰ atoms/cm³ and about 1×10²¹ atoms/cm³. In one exemplary embodiment, the silicon films are doped by ion-implantation. In another exemplary embodiment, the ion-implantation occurs in a vertical direction (i.e., a direction perpendicular to substrate 200). When gate electrode 212 is a polysilicon gate electrode, gate electrode 212 can be doped during the ion-implantation process. Gate electrode 212 acts as a mask to prevent the ion-implantation step from doping the channel region (not indicated) of the tri-gate transistor. The channel region is the portion of the semiconductor body 208 located beneath or surrounded by the gate electrode 212. If gate electrode 212 is a metal electrode, a dielectric hard mask maybe used to block the doping during the ion-implantation process. In other exemplary embodiments, other exemplary methods, such as solid-source diffusion, may be used to dope the semiconductor body to form source and drain extensions. In another exemplary embodiment, source and drain regions 216 and 217 include a semiconductor film (not shown) that is formed on the exposed surfaces of semiconductor body 207 to form source and drain contact regions. In another exemplary embodiment, the semiconductor film (not shown) would be grown after recess etching the fin in the source-drain areas and the semiconductor film would be used to strain the channel. One example would be strained silicon germanium SiGe. Another example would be strained silicon carbide SiC.

In exemplary embodiments, “halo” regions (not shown) can be formed in semiconductor body 207 prior to the formation of a source/drain regions or source/drain extension regions. Halo regions are doped regions formed in the channel region of the device and are of the same conductivity, but of a slightly higher concentration than the doping of the channel region of the device. Halo regions can be formed by ion-implanting dopants beneath the gate electrode by utilizing large angled ion-implantation techniques.

Next, if desired, the substrate can be further processed to form additional features, such as heavily doped source/drain contact regions, deposited silicon on the source and drain regions, as well as the gate electrode, and source/drain contacts can be formed as well as on the gate electrode. The source/drain contacts can be formed by depositing a metal around the fin and either reacting it or leaving it unreacted. If leaving the deposited metal unreacted, then the metal in the unwanted regions would be removed.

In one exemplary embodiment, dielectric sidewall spacers 218 (FIG. 2F) can be formed on the sidewalls of the gate electrode 212. Sidewall spacers 218 can be utilized to offset heavy source/drain contact implants, can be used to isolate source/drain regions from the gate electrode during a selective silicon deposition processes. Spacers 218 could be formed by blanket depositing a conformal dielectric film, such as, but not limited to, silicon nitride, silicon oxide, silicon oxynitride or combinations thereof over the substrate 200. The dielectric film forming spacers 218 is deposited conformal manner so that the dielectric film forms to substantially equal heights on vertical surfaces, such as the sidewalls of gate electrode 212, as well as on horizontal surfaces, such as on the top of semiconductor body 207 and the top of gate electrode 212. In one exemplary embodiment, the dielectric film is a silicon nitride film formed by a hot-wall low-pressure chemical vapor deposition (LPCVD) process. The deposited thickness of the dielectric film determines the width or thickness of the formed spacers. In an exemplary embodiment, the dielectric film is formed to a thickness of between about 20 Å and about 200 Å.

Next, the dielectric film is anisotropically etched, for example, plasma etching or reactive ion etching to form sidewall spacers 218, as depicted in FIG. 2F. The anisotropic etch of dielectric film removes the dielectric film from horizontal surfaces, such as the top of gate electrode 212 (as well as the top of landing pads (not shown) if used) and leaves dielectric sidewall spacers adjacent to vertical surfaces, such as sidewalls of gate electrode 212. The etch is continued for a sufficient period of time to remove the dielectric film from all horizontal surfaces. In an exemplary embodiment, an over etch is utilized so that the spacer material on the sidewalls of the semiconductor bodies 207 is removed, as depicted in FIG. 2F. The result is the formation of sidewall spacers 218 that run along and adjacent to the sidewalls of gate electrode 212, as depicted in FIG. 2F. The height of sidewall spacers 218 is depicted as being less that the height of gate electrode 212.

Next, if desired, a semiconductor film 219 can be formed on the exposed surfaces of semiconductor body 207 (as well as on landing pads (not shown)), as depicted in FIG. 2G. Additionally, if desired, a semiconductor film 220 can be formed on the top of gate electrode 212. Semiconductor film 220 could be a single crystalline film or a polycrystalline film. In an exemplary embodiment, semiconductor film 219 is an epitaxial (single crystalline) silicon film. In one exemplary embodiment, silicon film 219 is formed by a selective deposition process in which silicon is formed only on exposed regions that contain silicon, such as the exposed top surface and sidewalls of semiconductor body 207. In a selective deposition process, the silicon film does not form on dielectric areas, such as sidewall spacers 218. When gate electrode 212 comprises a polycrystalline silicon film, the semiconductor film would also selectively form on the top surface of gate electrode 212 to form silicon film 220. In one exemplary embodiment, silicon film 220 is formed to a thickness of between about 50 Å and about 500 Å. The silicon film can be insitu doped (i.e., doped during deposition) or subsequently doped by for example ion-implantation or solid-source diffusion. The silicon film is doped to the conductivity type desired for the source and drain regions of the device. In an exemplary embodiment, the deposited silicon films 219 and 220 are intrinsic silicon films (i.e., undoped silicon films). The deposition of semiconductor film 219 forms raised source and drain regions that improves the parasitics of the device.

In one exemplary embodiment, as depicted in FIG. 2H, the deposited silicon films 219 and 220 are doped by ion-implantation utilizing a vertical ion-implantation angle. The ion-implantation process dopes the deposited silicon film 219 and semiconductor body 207 located underneath to a concentration of between about 1×10²⁰ atoms/cm³ and about 1×10²¹ atoms/cm³ to form a source contact region 216 and a drain contact region (not indicated in FIG. 2H). Sidewall spacers 218 offset the source/drain contact implantation step and define the tip regions (not shown) as a region of the doped silicon body beneath sidewall spacer 218. Thus, the fabrication process source regions 216 and drain regions 217 (not shown in FIG. 2H) that each comprise a tip region and a contact region. The tip region (not shown) is the region of the semiconductor body 207 located beneath sidewall spacers 218. The contact regions are the regions of semiconductor body 207 and deposited silicon film 219 that are adjacent to the outside edges of the sidewall spacers 218. Additionally, the source/drain contact regions include the source and drain landing pads (not shown) when utilized.

Next, metal 221 is formed on the source and drain regions in a wrap-around configuration, as well as on the top of gate electrode 212. In one exemplary embodiment, a trench for forming contact vias is formed in an ILD layer, such as deposited SiO₂ (not shown) so that the top and sidewalls of the source and drain regions are exposed. Metal 221 is deposited then on the exposed portions of the source and drain regions by using a CVD technique. In another exemplary embodiment, metal 221 is formed on the exposed portions of the source and drain regions using an ALD technique. The rest of the via is filled with a metal like tungsten. Tungsten and the contact metal are removed from areas out side the vias with chemical mechanical polishing. In another exemplary embodiment, metal is deposited inside the via hole and reacted to form a metal silicide that does not consume the whole fin, then the via is filled with a via metal and chemical mechanical polishing is used to remove metal from outside the vias. In another exemplary embodiment, a silicide can be formed on the surfaces of the source and drain regions in contact with metal 221 by heat treating the device. In one exemplary embodiment, the silicide is formed so that it does not consume an entire source region or an entire drain region so that the interface area between metal 221 and the source and drain regions is kept proportional to the fin height. Excess metal 221 is then removed, such as by chemical etching. In one exemplary embodiment in which a Hi-K metal gate is used, no silicide would be formed on the gate. Step 305 in FIG. 3 corresponds to this portion of fabricating a tri-gate transistor in accordance with embodiments of the subject matter disclosed herein. Metal 221 can be formed from a material that provides a good contact to the source and drain regions, such as, but not limited to, titanium, tungsten, nickel, copper, or cobalt, or any other metal that has a contact resistance equal to or less than the contact resistance of NiSi. Metal 221 is formed on the source and drain regions to form source and drain contact regions so that contact area advantageously scales as the fin height increases.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A semiconductor device, comprising:
a substrate; and
a semiconductor body formed on the substrate, the semiconductor body comprising a source region and a drain region, at least one of the source region and the drain region comprising a first side surface, a second side surface, and a top surface, the first side surface being opposite the second side surface,
metal layer formed on substantially all of the first side surface, substantially all of the second side surface, and the top surface of the at least one of the source region and the drain region.

2. The semiconductor device according to claim 1, wherein the metal layer provides a contact surface with substantially all of the first and second side surfaces that proportionally scales with a height of the semiconductor body.

3. The semiconductor device according to claim 2, wherein the substrate comprises an insulative substrate or a bulk substrate.

4. The semiconductor device according to claim 3, wherein the metal layer comprises titanium, tungsten, nickel, copper, or cobalt, or any other metal comprising a contact resistance equal to or less than a contact resistance of NiSi, or combinations thereof.

5. The semiconductor device according to claim 4, further comprising:
a gate dielectric layer formed on the first side surface, the second side surface and the top surface of the semiconductor body between the source region and the drain region, and
a gate electrode formed on the gate dielectric layer.

6. The semiconductor device according to claim 1, further comprising:
a gate dielectric layer formed on the first side surface, the second side surface and the top surface of the semiconductor body between the source region and the drain region, and
a gate electrode formed on the gate dielectric layer.

7. The semiconductor device according to claim 6, wherein the metal layer provides a contact surface with substantially all of the first and second side surfaces that proportionally scales with a height of the semiconductor body.

8. The semiconductor device according to claim 7, wherein the metal layer comprises titanium, tungsten, nickel, copper, or cobalt, or any other metal comprising a contact resistance equal to or less than a contact resistance of NiSi, or combinations thereof.

9. The semiconductor device according to claim 8, wherein the substrate comprises an insulative substrate or a bulk substrate.

10. A method for forming a semiconductor device, the method comprising:
providing a substrate; and
forming a semiconductor body on the substrate, the semiconductor body comprising a source region and a drain region, at least one of the source region and the drain region comprising a first side surface, a second side surface, and a top surface, the first side surface being opposite the second side surface, and
forming a metal layer on substantially all of the first side surface, substantially all of the second side surface, and the top surface of the at least one of the source region and the drain region.

11. The method according to claim 10, wherein the metal layer provides a contact surface with substantially all of the first and second side surfaces that proportionally scales with a height of the semiconductor body.

12. The method according to claim 11, wherein the substrate comprises an insulative substrate or a bulk substrate.

13. The method according to claim 12, wherein the metal layer comprises titanium, tungsten, nickel, copper, or cobalt, or any other metal comprising a contact resistance equal to or less than a contact resistance of NiSi, or combinations thereof.

14. The method according to claim 13, further comprising:
forming a gate dielectric layer on the first side surface, the second side surface and the top surface of the semiconductor body between the source region and the drain region, and
forming a gate electrode on the gate dielectric layer.

15. The method according to claim 10, further comprising:
forming a gate dielectric layer on the first side surface, the second side surface and the top surface of the semiconductor body between the source region and the drain region, and
forming a gate electrode on the gate dielectric layer.

16. The method according to claim 15, wherein the metal layer provides a contact surface with substantially all of the first and second side surfaces that proportionally scales with a height of the semiconductor body.

17. The method according to claim 16, wherein the metal layer comprises titanium, tungsten, nickel, copper, or cobalt, or any other metal comprising a contact resistance equal to or less than a contact resistance of NiSi, or combinations thereof.

18. The method according to claim 17, wherein the substrate comprises an insulative substrate or a bulk substrate.
